(19) United States
(12) Patent Application Publication
(10) Pub. No.: US 2024/0310559 A1
(43) Pub. Date: Sep. 19, 2024

(54) MINIATURE MULTIFUNCTIONAL VR RESIN LENS AND PREPARATION METHOD THEREOF

(71) Applicant: Jiangsu Conant Optical Co. Ltd, Nantong (CN)

(72) Inventors: Qingbo Yan, Nantong (CN); Chuanbao Wang, Nantong (CN)

(21) Appl. No.: 18/495,658

(22) Filed: Oct. 26, 2023

(30) Foreign Application Priority Data
Mar. 14, 2023 (CN) 202310240895.5

(51) Int. Cl. G02B 1/04; G02B 1/11; G02B 1/12; G02B 1/14; G02B 1/18

(52) U.S. Cl. CPC G02B 1/041; G02B 1/11; G02B 1/12; G02B 1/14; G02B 1/18

(57) ABSTRACT

Disclosed is a miniature multifunctional VR resin lens, including a lens base, wherein the lens base is a multifunctional resin base, a multifunctional hard layer is disposed on the lens base, and a multifunctional film layer is disposed on the multifunctional hard layer. The lens of the present disclosure has an anti-blue light function, a color change performance, a light anti-reflection function, an anti-electromagnetic radiation function, a waterproof performance, an anti-fog performance, an anti-scratch performance, and a dyeability performance. Meanwhile, the miniature multifunctional VR resin lens may be enabled to match diopters required by human eyes, and is simple in structure, stable in performance, and low in construction cost.

### CROSS-REFERENCE TO RELATED APPLICATIONS

This application claims priority of Chinese Patent Application No. 202310240895.5, filed on Mar. 14, 2023, the entire contents of which are incorporated herein by reference.

### TECHNICAL FIELD

The present disclosure relates to the technical field of VR lenses, and particularly to a miniature multifunctional VR resin lens and a preparation method thereof.

### BACKGROUND

A virtual reality technology is a computer simulation system that can create and provide experience of a virtual world. The virtual reality technology uses a computer to generate a simulation environment, which is a system simulation of a multi-source information fused and interactive three-dimensional dynamic visual scene and an entity behavior, that immerses a user into the environment. With the advancement of technologies, the development of technologies applied to wearable devices becomes increasingly rapid, followed by an increase in the variety of wearable devices, thus satisfying continuously growing demands of users. A virtual reality head mounted display device, referred to as VR headset or VR glasses for short, is a novel wearable device that employs computer and sensor technologies to achieve a new human-computer interaction pattern, thereby achieving better user experience. Both pieces of glass of the VR glasses are provided with lenses, and the two lenses are equivalent to human eyes. The VR glasses usually display contents on two half screens. The displayed contents are superimposed and imaged on retinas of the human eyes after focusing and zooming-in using the two lenses, so as to create a new simulation environment in a human brain and ultimately bring a sense of immersion to the user.

### Defects in the Existing Technology

However, the users of the VR glasses are concentrated in the highly educated populations. A survey indicates that the incidence of myopia in China currently reaches more than 70% in the population with degrees above high school. Without wearing glasses during use of the VR glasses, nearsighted users often cannot see characters on the screen clearly, let alone experiencing the sense of immersion, thereby reducing the popularity of VR devices. Currently, the VR glasses in China are all claimed as not being affected by near sight of 4.0 or higher diopters. For example, Oculus proposed a solution to this problem by providing three sets of lenses with different diopters, which is equivalent to providing 3 sets of lenses with different refractive powers from the perspective of the optical principle. Most of the VR glasses in China are provided with only one set of lenses, and generally solve the near sight problem by two methods. One method is to wear glasses and then wear the VR glasses. Such method solves the near sight problem while greatly weakening the sense of immersion, because the human eyes cannot get close to the lenses, and the solution of wearing two pairs of glasses at the same time is also very clumsy. The other method is to place the screen or a mobile phone close to the lenses without wearing glasses, which is equivalent to that the nearsighted user approaches the screen to watch the content on the screen. Such method also weakens the sense of immersion, because it is equivalent to removing images at the edge of the screen from the screen, so that the nearsighted user can only see images on a middle part, while images on the outer side are cut off. Another defect of this method is that the nearsighted user is more likely to see pixels, resulting in a so-called screen door effect. Additionally, if the left and right eyes of the user have different diopters, this method cannot solve the problem.

In addition, the conventional VR glasses have only a single light transmission function, which cannot satisfy requirements for the visual experience of the user and protection of the glasses.

### SUMMARY

The present disclosure aims to provide a miniature multifunctional VR resin lens and a preparation method thereof to solve the problems as proposed in the above Background.

A miniature multifunctional VR resin lens comprises a lens base, wherein the lens base is a multifunctional resin base, a multifunctional hard layer is disposed on the lens base, and a multifunctional film layer is disposed on the multifunctional hard layer.

As a further improvement of the present disclosure, the lens base is made of any one of acrylate, polyurethane, polycarbonate, and allyl carbonate.

As a further improvement of the present disclosure, the multifunctional hard layer comprises one or more of an anti-scratch layer, an anti-impact layer, and a dyeable hardened layer.

As a further improvement of the present disclosure, the multifunctional film layer comprises any one of a light anti-reflection film, an anti-electromagnetic radiation film, a waterproof film, and an anti-fog film.

As a further improvement of the present disclosure, a visible light transmittance of the light anti-reflection film in the multifunctional film layer is 90%-99%.

As a further improvement of the present disclosure, the anti-electromagnetic radiation film in the multifunctional film layer is made of an indium tin oxide layer, the waterproof film in the multifunctional film layer is made of fluoride, and the anti-fog film in the multifunctional film layer is made of a hydrophilic material. As a further improvement of the present disclosure, the lens base is either of a single vision lens or an astigmatic lens, and a single face area of a light transmitting face of the lens base ranges from 251 mm² to 1260 mm².

The present disclosure further discloses a preparation method of a miniature multifunctional VR resin lens, wherein the preparation method comprises: S1. material mixing and curing; S2. surface treatment; and S3. vacuum plating, wherein:
S1. material mixing and curing: selecting any one of acrylate, polyurethane, polycarbonate, and allyl carbonate as a raw material, adding an aid, an initiator, and an anti-blue light toner for uniform mixing, and performing heating and insulation curing in a curing oven to obtain a lens base;
S2. surface treatment: performing surface hardening treatment on the lens base obtained in step S1 to obtain a multifunctional hard layer; and
S3. vacuum plating: vacuum-plating the multifunctional hard layer obtained in step S2 with any one or more of a light anti-reflection layer, an indium tin oxide layer, a fluoride layer, and a hydrophilic material to obtain a light anti-reflection film, an anti-electromagnetic radiation film, a waterproof film, and an anti-fog film.

As a further improvement of the present disclosure, the multifunctional hard layer has multiple functions including any one or more of an anti-blue light performance, a color change performance, and a dyeability performance.

As a further improvement of the present disclosure, the anti-blue light performance comprises a light transmittance of 0-5% for visible light at wavelengths of 380 nm-410 nm, and the color change performance comprises changing the base of the VR resin lens into any one of a red base, an orange base, a yellow base, a green base, a cyan base, a blue base, a purple base, a gray base, and a brown base.

Compared with the existing technology, the present disclosure has the following beneficial effects:
The lens of the present disclosure has an anti-blue light function, a color change performance, a light anti-reflection function, an anti-electromagnetic radiation function, a waterproof performance, an anti-fog performance, an anti-scratch performance, and a dyeability performance. Meanwhile, the miniature multifunctional VR resin lens may be enabled to match diopters required by human eyes, and is simple in structure, stable in performance, and low in construction cost.

### BRIEF DESCRIPTION OF THE DRAWINGS

FIG. 1 is a schematic structural diagram of a miniature multifunctional VR resin lens of the present disclosure;

FIG. 2 is a flow diagram of a preparation method of a miniature multifunctional VR resin lens of the present disclosure;

FIG. 3 is a diagram of a material object obtained by material mixing and curing in Embodiment 2 of the present disclosure;

FIG. 4 is a diagram of a material object obtained by surface treatment in Embodiment 2 of the present disclosure;

FIG. 5 is a diagram of a material object obtained by vacuum plating in Embodiment 2 of the present disclosure; and

FIG. 6 is a diagram of a material object obtained by beveling treatment in Embodiment 2 of the present disclosure.

In the drawings: 1. lens base; 2. multifunctional hard layer; and 3. multifunctional film layer.

### DETAILED DESCRIPTION

The technical solution in embodiments of the present disclosure will be clearly and completely described below in conjunction with the drawings in the embodiments of the present disclosure. Apparently, the described embodiments are only part, but not all, of the embodiments of the present disclosure. Based on the embodiments in the present disclosure, all other embodiments obtained by those of ordinary skills in the art without the exercise of inventive effort fall within the scope of protection of the present disclosure.

### Embodiment 1

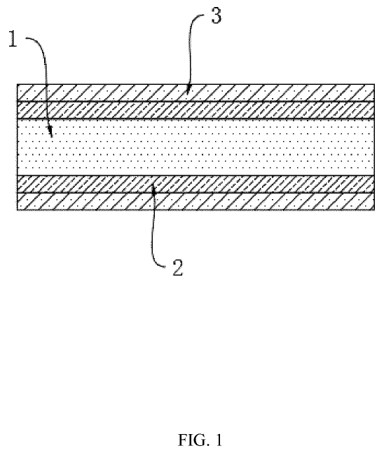

Referring to FIG. 1, the present disclosure provides the following technical solution: a miniature multifunctional VR resin lens, including a lens base 1, wherein the lens base 1 is a multifunctional resin base, a multifunctional hard layer 2 is disposed on the lens base 1, and a multifunctional film layer 3 is disposed on the multifunctional hard layer 2.

The lens base 1 is made of any one of acrylate, polyurethane, polycarbonate, and allyl carbonate. The lens base 1 is a single vision lens, and a single face area of a light transmitting face of the lens base 1 is 892 mm².

The multifunctional hard layer 2 includes an anti-scratch layer, an anti-impact layer, and a dyeable hardened layer.

The multifunctional film layer 3 includes a light anti-reflection film, an anti-electromagnetic radiation film, a waterproof film, and an anti-fog film. A visible light transmittance of the light anti-reflection film in the multifunctional film layer 3 is 90%-99%. The anti-electromagnetic radiation film in the multifunctional film layer 3 is made of an indium tin oxide layer, the waterproof film in the multifunctional film layer 3 is made of fluoride, and the anti-fog film in the multifunctional film layer 3 is made of a hydrophilic material.

### Embodiment 2

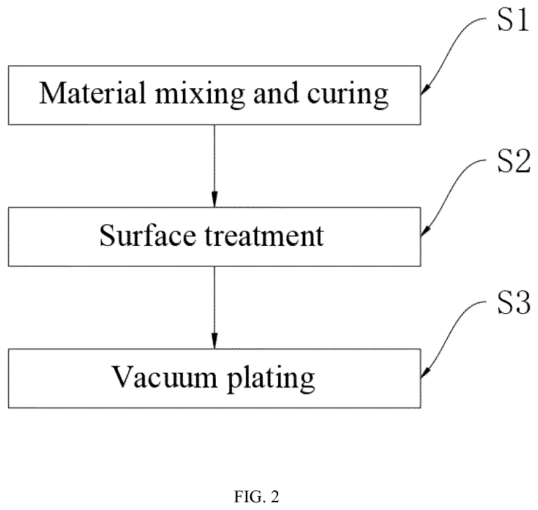

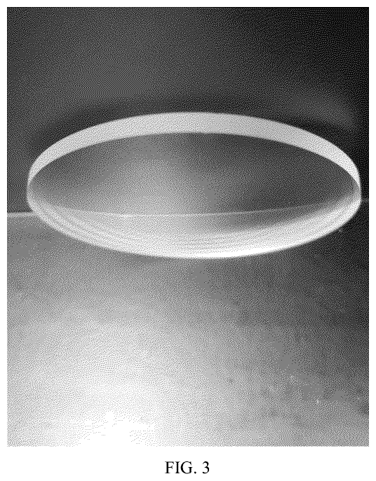

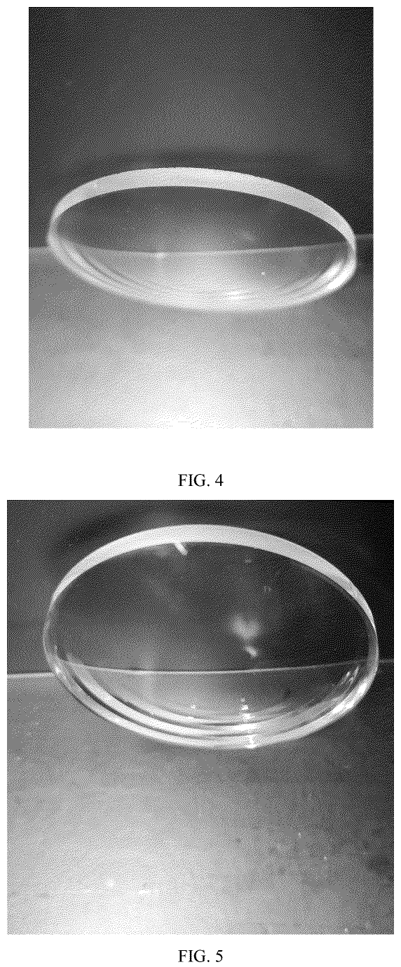

Referring to FIGS. 2-6, the present disclosure further provides the following technical solution: a preparation method of the miniature multifunctional VR resin lens, wherein the preparation method includes: S1. material mixing and curing; S2. surface treatment; and S3. vacuum plating, wherein:
S1. material mixing and curing: selecting acrylate as a raw material, adding an aid, an initiator, and an anti-blue light toner for uniform mixing, and performing heating and insulation curing in a curing oven to obtain a lens base 1 as shown in FIG. 3;
S2. surface treatment: performing surface hardening treatment on the lens base 1 as shown in FIG. 3 to obtain a multifunctional hard layer 2, as shown in FIG. 4; and
S3. vacuum plating: vacuum-plating the multifunctional hard layer 2 as shown in FIG. 4 with a light anti-reflection layer, an indium tin oxide layer, a fluoride layer, and a hydrophilic material to obtain a light anti-reflection film, an anti-electromagnetic radiation film, a waterproof film, and an anti-fog film, thereby obtaining a lens as shown in FIG. 5.

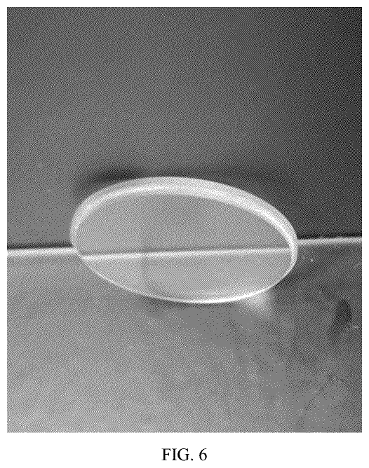

Finally, beveling treatment is performed on the lens as shown in FIG. 5 to obtain a lens as shown in FIG. 6.

The multifunctional hard layer 2 has multiple functions including an anti-blue light performance, a color change performance, and a dyeability performance.

The anti-blue light performance includes a light transmittance of 3% for visible light at a wavelength of 410 nm.

The color change performance includes changing the base of the VR resin lens into any one of a red base, an orange base, a yellow base, a green base, a cyan base, a blue base, a purple base, a gray base, and a brown base.

A dyeable base is a single-color or multicolor dyeable base.

### Embodiment 3

Referring to FIG. 2, the present disclosure further provides the following technical solution: a preparation method of a miniature multifunctional VR resin lens, wherein the preparation method includes: S1. material mixing and curing; S2. surface treatment; and S3. vacuum plating, wherein:
S1. material mixing and curing: selecting polyurethane as a raw material, adding an aid, an initiator, and an anti-blue light toner for uniform mixing, and performing heating and insulation curing in a curing oven to obtain a lens base 1;
S2. surface treatment: performing surface hardening treatment on the lens base 1 to obtain a multifunctional hard layer 2; and
S3. vacuum plating: vacuum-plating the multifunctional hard layer 2 with a light anti-reflection layer, an indium tin oxide layer, a fluoride layer, and a hydrophilic material to obtain a light anti-reflection film, an anti-electromagnetic radiation film, a waterproof film, and an anti-fog film, thereby obtaining a lens.

Finally, beveling treatment is performed on the lens to obtain a lens.

The multifunctional hard layer 2 has multiple functions including an anti-blue light performance, a color change performance, and a dyeability performance.

The anti-blue light performance includes a light transmittance of 3% for visible light at a wavelength of 410 nm.

The color change performance includes changing the base of the VR resin lens into any one of a red base, an orange base, a yellow base, a green base, a cyan base, a blue base, a purple base, a gray base, and a brown base.

A dyeable base is a single-color or multicolor dyeable base.

### Comparative Embodiment 1

An aid and an initiator are added to a raw material acrylic monomer for uniform mixing, heating and insulation curing is performed in a curing oven to obtain a resin lens, and beveling treatment is performed on the resin lens to obtain a VR lens.

### Comparative Embodiment 2

An aid and an initiator are added to a raw material polyurethane monomer for uniform mixing, heating and insulation curing is performed in a curing oven to obtain a resin lens, and beveling treatment is performed on the resin lens to obtain a VR lens.

Optical transmittance tests, anti-blue light tests, electromagnetic radiation tests, water drop contact angle tests, and wear resistance tests are performed on the lenses obtained in Embodiment 2 and Embodiment 3 and the lenses obtained in Comparative Embodiment 1 and Comparative Embodiment 2. Instruments used include an optical transmittance tester TM-8S, an electromagnetic radiation tester, a water drop contact angle tester, and a wear resistance tester, and obtained results are shown in a table below:

| | | Anti- | Anti- | Water | Wear |
|---|---|---|---|---|---|
| | Light | blue | electro- | drop | resistance |
| | trans- | light | magnetic | contact | against a |
| | mittance | function | wave test | angle | 750 g weight |
| Embodiment 2 | 94.68% | Yes | Yes | 108° | No damage |
| Embodiment 3 | 97.24% | Yes | Yes | 103° | No damage |
| Comparative | 90.66% | No | No | 44° | Damage |
| Embodiment 1 | | | | | |
| Comparative | 92.05% | No | No | 46° | Damage |
| Embodiment 2 | | | | | |

It can be seen from the above table that the lenses produced by processes of the present disclosure have an optical transmittance performance of greater than 90%, have the anti-blue light function with an absorption rate for 380-500 nm blue light reaching 15%-25%, and have a better anti-electromagnetic effect, better water drop contact angle performance, and better wear resistance performance than lenses produced by conventional processes. The VR lens is integrated with various functions, can match diopters required by a human eye, and is simple in structure, stable in performance, and low in construction cost.

It should be noted that, the relational terms such as “first” and “second”, etc. herein are merely used to distinguish one entity or operation from another entity or operation, and do not necessarily require or imply any actual relationship or order between these entities or operations. Moreover, the terms “include”, “comprise”, or any other variations thereof are intended to cover non-exclusive inclusions, such that a process, method, item, or device that includes a series of elements not only includes these elements, but also includes other elements that are not explicitly listed, or also includes elements inherent in such process, method, item, or device.

Although the embodiments of the present disclosure have been illustrated and described, those of ordinary skills in the art may understand that multiple changes, modifications, substitutions, and variations may be made to these embodiments without departing from the principle and spirit of the present disclosure. The scope of the present disclosure is defined by the claims and equivalents thereof.

1. A miniature multifunctional VR resin lens, comprising a lens base (1), wherein the lens base (1) is a multifunctional resin base, a multifunctional hard layer (2) is disposed on the lens base (1), and a multifunctional film layer (3) is disposed on the multifunctional hard layer (2).

2. The miniature multifunctional VR resin lens of claim 1, wherein the lens base (1) is made of any one of acrylate, polyurethane, polycarbonate, and allyl carbonate.

3. The miniature multifunctional VR resin lens of claim 1, wherein the multifunctional hard layer (2) comprises one or more of an anti-scratch layer, an anti-impact layer, and a dyeable hardened layer.

4. The miniature multifunctional VR resin lens of claim 1, wherein the multifunctional film layer (3) comprises any one of a light anti-reflection film, an anti-electromagnetic radiation film, a waterproof film, and an anti-fog film.

5. The miniature multifunctional VR resin lens of claim 4, wherein a visible light transmittance of the light anti-reflection film in the multifunctional film layer (3) is 90%-99%.

6. The miniature multifunctional VR resin lens of claim 4, wherein the anti-electromagnetic radiation film in the multifunctional film layer (3) is made of an indium tin oxide layer, the waterproof film in the multifunctional film layer (3) is made of fluoride, and the anti-fog film in the multifunctional film layer (3) is made of a hydrophilic material.

7. The miniature multifunctional VR resin lens of claim 1, wherein the lens base (1) is one of a single vision lens or an astigmatic lens, and a single face area of a light transmitting face of the lens base (1) ranges from 251 mm² to 1260 mm².

8. A preparation method of the miniature multifunctional VR resin lens of claim 1, wherein the preparation method comprises: S1. material mixing and curing; S2. surface treatment; and S3. vacuum plating, wherein:
S1. material mixing and curing: selecting any one of acrylate, polyurethane, polycarbonate, and allyl carbonate as a raw material, adding an aid, an initiator, and an anti-blue light toner for uniform mixing, and performing heating and insulation curing in a curing oven to obtain the lens base (1);
S2. surface treatment: performing surface hardening treatment on the lens base (1) obtained in step S1 to obtain the multifunctional hard layer (2); and
S3. vacuum plating: vacuum-plating the multifunctional hard layer (2) obtained in step S2 with any one or more of a light anti-reflection layer, an indium tin oxide layer, a fluoride layer, and a hydrophilic material to obtain the light anti-reflection film, the anti-electromagnetic radiation film, the waterproof film, and the anti-fog film.

9. A preparation method of the miniature multifunctional VR resin lens of claim 2, wherein the preparation method comprises: S1. material mixing and curing; S2. surface treatment; and S3. vacuum plating, wherein:
S1. material mixing and curing: selecting any one of acrylate, polyurethane, polycarbonate, and allyl carbonate as a raw material, adding an aid, an initiator, and an anti-blue light toner for uniform mixing, and performing heating and insulation curing in a curing oven to obtain the lens base (1);
S2. surface treatment: performing surface hardening treatment on the lens base (1) obtained in step S1 to obtain the multifunctional hard layer (2); and
S3. vacuum plating: vacuum-plating the multifunctional hard layer (2) obtained in step S2 with any one or more of a light anti-reflection layer, an indium tin oxide layer, a fluoride layer, and a hydrophilic material to obtain the light anti-reflection film, the anti-electromagnetic radiation film, the waterproof film, and the anti-fog film.

10. The preparation method of the miniature multifunctional VR resin lens of claim 8, wherein the multifunctional hard layer (2) has multiple functions including any one or more of an anti-blue light performance, a color change performance, and a dyeability performance.

11. The preparation method of the miniature multifunctional VR resin lens of claim 9, wherein the anti-blue light performance comprises a light transmittance of 0-5% for visible light at wavelengths of 380 nm-410 nm, and the color change performance comprises changing the base of the VR resin lens into any one of a red base, an orange base, a yellow base, a green base, a cyan base, a blue base, a purple base, a gray base, and a brown base.
